(19) United States
(12) Patent Application Publication
(10) Pub. No.: US 2002/0135046 A1
(43) Pub. Date: Sep. 26, 2002

(54) Bipolar junction transistor with high ESD robustness and low load-capacitance

(75) Inventor: Ta-Lee Yu, Hsinchu Hsien (TW)

Correspondence Address: Richard P. Berg, Esq., c/o LADAS & PARRY, Suite 2100, 5670 Wilshire Boulevard, Los Angeles, CA, 90036-5679, US

(73) Assignee: Winbond Electronics Corp.

(21) Appl. No.: 10/053,162

(22) Filed: Jan. 15, 2002

(30) Foreign Application Priority Data
Mar. 26, 2001 (TW) 90107055

(51) Int. Cl. H01L 27/082

(52) U.S. Cl. 257/579; 257/565; 257/591; 257/546

(57) ABSTRACT

According to the object, the present invention provides an electrostatic discharge (ESD) circuit, coupled between a pad and a power line. The ESD protection circuit comprises a bipolar junction transistor (BJT) . The BJT comprises a collector region having a first conductivity type, formed in a substrate, in contact with a buried layer having the first conductivity type, and coupled to the pad to become the collector of the BJT, a base region having the second conductivity type, formed on the buried layer to become the base of the BJT, and an emitter having the first conductivity type, formed in the base region and coupled to the power line to become the emitter of the BJT. The emitter has a plurality of parallel first regions and a second region connecting the first regions.

### BACKGROUND OF THE INVENTION

1. Field of the Invention

The present invention relates in general to a bipolar junction transistor (BJT) for I/O ports. In particular, the present invention relates to a BJT capable of sustaining high electrostatic discharge (ESD) and having low load-capacitance.

2. Description of the Related Art

BJT units are usually used as ESD protection for I/O ports in integrated circuits (IC) on which they are installed as primary components. ESD stress is released through the snapback effect of the BJT during ESD.

The layout of a conventional npn BJT is shown in FIG. 1A; the cross-section of the npn BJT in FIG. 1A is shown in FIG. 1B; and the npn BJT in FIG. 1A is coupled to a pad to become an ESD protection component is shown in FIG. 1C. An N+ diffusion 12 is electrically coupled with an N-type layer 24 and an N+ doped buried layer 20 to become the collector of the npn BJT; a P+ diffusion 16 is located in a P-well 14 to become the base of the npn BJT; and an N+ diffusion 18 is located in the P-well 14 to become the emitter of the npn BJT. The primary structure of the npn BJT is formed by the N+ diffusion 18, the P-well 14 and the N-type layer 24. The N+ diffusion 12, the P+ diffusion 16 and the N+ diffusion 18 are parallel as shown in FIG. 1A. The collector of the npn BJT is coupled to the pad 30 and the emitter is coupled to the VSS power line for the BJT device to function as an ESD protection component.

To simultaneously qualify as a current driver, the npn BJT in FIG. 1A must be wide enough to achieve sufficient current driving power. FIG. 1A shows an example of the BJT device having a width of 100 μmso that the emitter area of the npn BJT is large enough to sustain high ESD stress.

The npn BJT in FIG. 1A, however, has two primary disadvantages. The layout of the components on the chip is massive, resulting in a rise in the fabrication costs. The input equivalent capacitance at the collector also increases to sequentially compromise the high-frequency response of the components.

FIG. 2 is a layout of another conventional npn BJT created to rectify the disadvantages referred to above, and simultaneously provide enough current driving power. The 100 μmN+ diffusion 18 in FIG. 1A is divided into four 25 μmN+ diffusion regions 18a-18d in FIG. 2, with little change in the driving current. Notably, the layout of the components is minimized for the N+ diffusion 12, as the collector of the BJT device, is shortened. The smaller collector area also indicates a decrease in the input equivalent capacitance on the pad.

Such a layout configuration, however, results in low ESD robustness of the npn BJT device. It is explicitly disclosed in U.S. Pat. No. 5,850,095 that the ESD robustness does not improve with the increased N+ diffusion regions 18. Realistically, the snapback to provide ESD protection only occurs at the PN diffusion between the N+ diffusion 18a closest to the P+ diffusion 16 and the P-well 14 due to the spread resistance of the P-well 14. Therefore, the npn BJT in FIG. 2 sustains lower ESD stress than that in FIG. 1.

### SUMMARY OF THE INVENTION

An object of the present invention is to provide an ESD protection component to realize small layout area, low input equivalent capacitance and good ESD robustness.

According to the object, the present invention provides an electrostatic discharge (ESD) circuit, coupled between a pad and a power line. The ESD protection circuit comprises a bipolar junction transistor (BJT) . The BJT comprises a collector region having a first conductivity type, formed in a substrate, in contact with a buried layer having the first conductivity type, and coupled to the pad to become the collector of the BJT, a base region having the second conductivity type, formed on the buried layer to become the base of the BJT, and an emitter having the first conductivity type, formed in the base region and coupled to the power line to become the emitter of the BJT. The emitter has a plurality of parallel first regions and a second region connecting the first regions.

The present invention further provides an electrostatic discharge (ESD) circuit, coupled between a pad and a power line. The ESD protection circuit comprises a bipolar junction transistor (BJT) . The BJT comprises a collector region having a first conductivity type, formed in a substrate, in contact with a buried layer having the first conductivity type, and coupled to the pad to become the collector of the BJT, a base region having the second conductivity type, formed on the buried layer to become the base of the BJT, and an emitter having the first conductivity type, formed in the base region and coupled to the power line to become the emitter of the BJT. The emitter is strip wound.

The first conductivity type can be N-type and the second conductivity type can be p-type.

The advantage of the present invention is that the breakdown occurs at one point of the PN junction formed by the emitter region and the base region, and the rest of the PN junction is sequentially broken down from the domino effect to trigger the whole npn BJT device so that the ESD current is released.

### BRIEF DESCRIPTION OF THE DRAWINGS

The present invention can be more fully understood by reading the subsequent detailed description in conjunction with the examples and references made to the accompanying drawings, wherein:

FIG. 1A indicates the layout of a conventional npn BJTthe FIG. 1B is a cross-section of the npn BJT in FIG. 1A;

FIG. 1C shows the npn BJT in FIG. 1A coupled to a pad to become an ESD protection component;

FIG. 2 is a layout of another conventional npn BJT;

FIG. 3A shows an embodiment of the npn BJT of the present invention;

FIGS. 3B and 3C are cross sections along the dotted lines aa′ and bb′ in FIG. 3A; and

FIGS. 4-6 are variations of the npn BJT of the present invention.

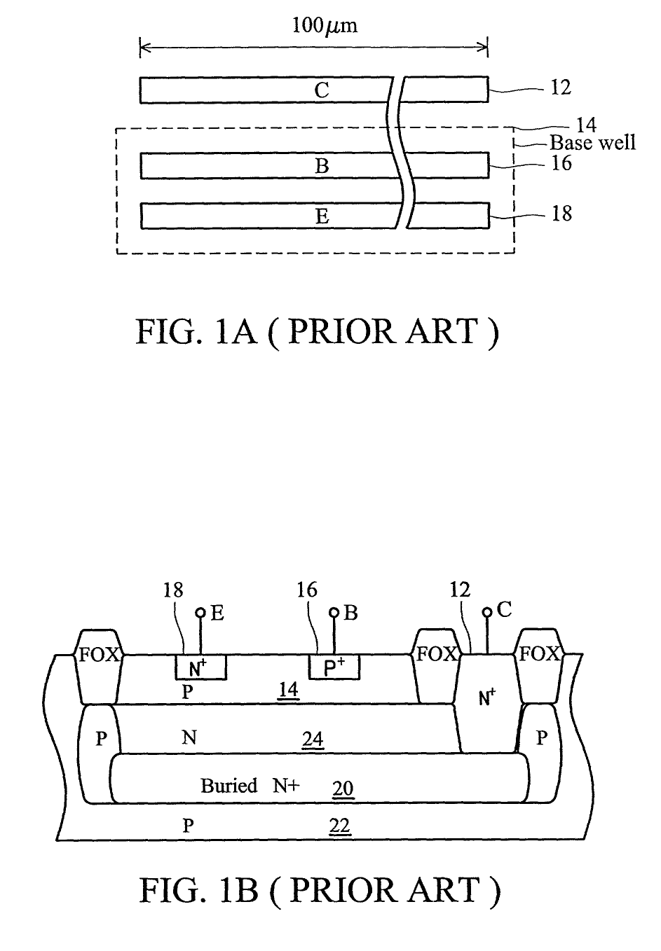

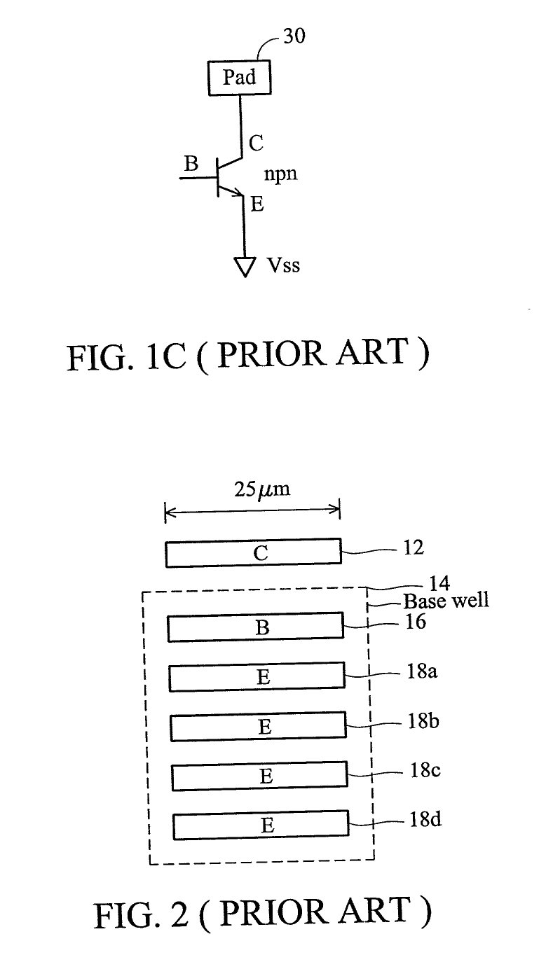

### DETAILED DESCRIPTION OF THE PREFERRED EMBODIMENT

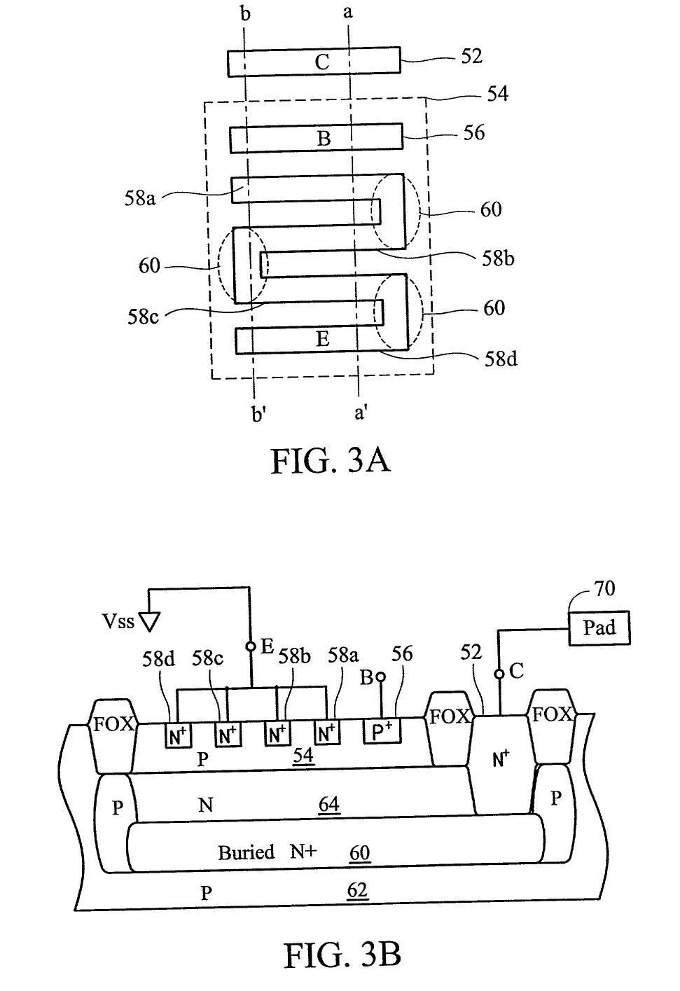

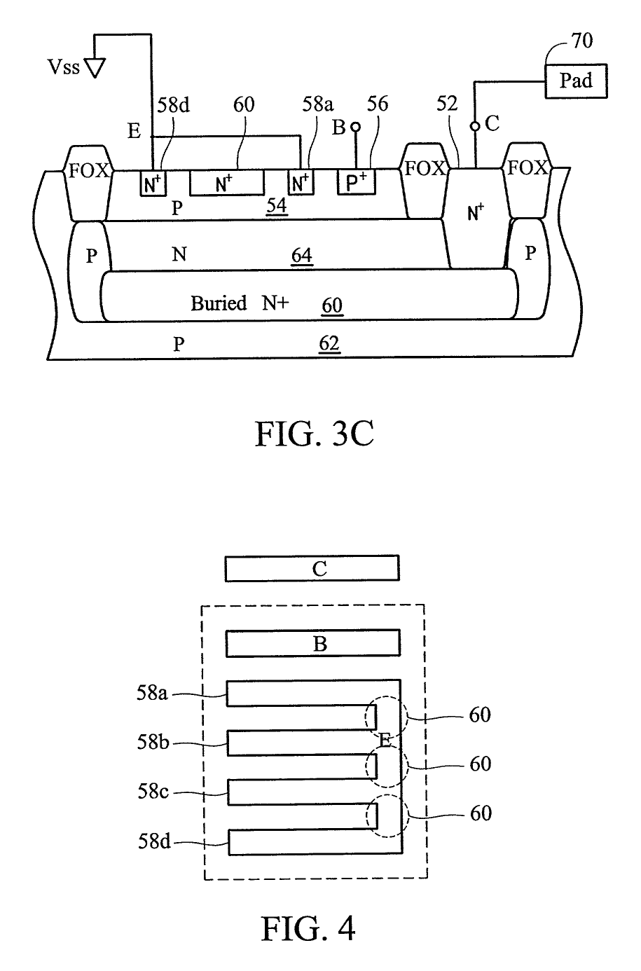

FIG. 3A shows an embodiment of the npn BJT of the present invention. The two cross sections along the dotted lines aa′ and bb′ in FIG. 3A are respectively shown in FIGS. 3B and 3C. An N+ diffusion 52 is in contact with an N-type layer 64 and an N+ doped buried layer 60 to become the collector of the npn BJT; a P+ diffusion 56 is located in a P-well 54 to become the base of the npn BJT; and parallel N+ diffusions 58a-58d and the connecting N+ diffusion 60 are located in the P-well 54 to become the emitter of the npn BJT and form a series of PN junctions with the P-well 54. The primary structure of the npn BJT is formed by the N+ diffusions 58a-58d, the P-well 54 and the N-type layer 54. The collector of the npn BJT is coupled to the pad 70 and the emitter is coupled to the VSS power line when the BJT device is coupled to the pad as the ESD protection component.

When a relatively positive ESD, with respect to VSS, pulses on the pad 70, the PN junction between the emitter and P-well 54 closet to the base breaks down first. According to semiconductor physics, the breakdown of the PN junction is a chain reaction. The breakdown at one point of the PN junction causes the domino effect of the sequential breakdown of the remaining PN junction. The breakdown occurs first at the PN junction between the N+ diffusion 58a and the P-well 54. Because the PN junction formed by the N+ diffusions 58a-58d and 60 is a continuous interface, the breakdown propagates along the interface to trigger the whole npn BJT device and dispatch the ESD current. The ESD stress is released by all the N+ diffusions 58a-58d and 60. The npn BJT thus has a high ESD robustness.

The area (in proportion to the length) of the N+ diffusion decides the input capacitance of the pad. The total layout area of the N+ diffusions 58a-58d and 60 (also in proportion to the length) determines the ESD driving current of the BJT of the present invention. As shown in FIG. 3A, the npn BJT of the present invention has high current driving power and low input capacitance, with the additional advantage of high ESD robustness. The npn BJT of the present invention achieves the advantages not altogether acquired by the prior art.

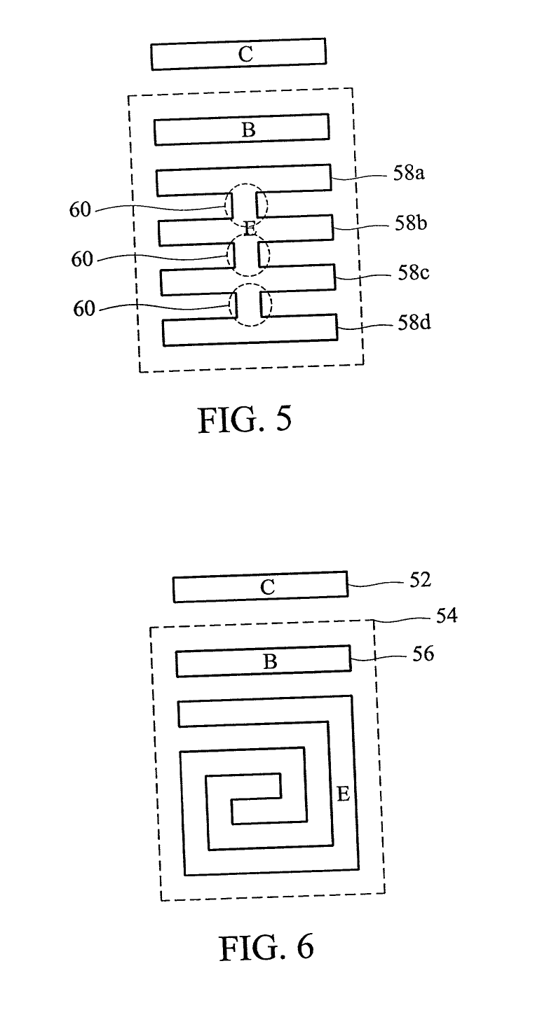

FIGS. 4-6 are the three variations of the npn BJT of the present invention. The shape of the emitter is arbitrarily manipulated under a condition such that the PN junction formed by the emitter and the P-well 54 must be continuous. The connecting N+ diffusion 60 is placed at the right and the middle of the N+ diffusions 58a-58d respectively in FIGS. 4 and 5. The emitter in FIGS. 4 has a finger-type pattern. In FIG. 6, the emitter has a serpentine pattern. The emitters in FIGS. 3A-6 are strip wound with continuous outlines to implement the object of the present invention.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. An electrostatic discharge (ESD) circuit, coupled between a pad and a power line, comprising a bipolar junction transistor (BJT), the BJT comprising:
a collector region having a first conductivity type, formed in a substrate, in contact with a buried layer having the first conductivity type, and coupled to the pad to become the collector of the BJT;
a base region having the second conductivity type, formed on the buried layer to become the base of the BJT; and
an emitter having the first conductivity type, formed in the base region and coupled to the power line to become the emitter of the BJT, the emitter having a plurality of parallel first regions and a second region connecting the first regions.

2. The ESD protection circuit in claim 1, wherein an emitter contact region is formed in the base region as an electric contact of the base region.

3. The ESD protection circuit in claim 1, wherein the second region is at the end of the first regions.

4. The ESD protection circuit in claim 1, wherein the second region connects the center of the first regions.

5. The ESD protection circuit in claim 1, wherein the substrate has a second conductivity type.

6. The ESD protection circuit in claim 1, wherein the first conductivity type is an N type and the second conductivity type is a p-type.

7. The ESD protection circuit in claim 1, wherein the first conductivity type is a p-type and the second conductivity type is a N-type.

8. The ESD protection circuit in claim 1, wherein the emitter has a serpentine pattern.

9. The ESD protection circuit in claim 1, wherein the emitter has a finger-type pattern.

10. An electrostatic discharge (ESD) circuit, coupled between a pad and a power line, comprising a bipolar junction transistor (BJT), the BJT comprising:
an N-type collector region, formed in a substrate, in contact with a buried layer having the first conductivity type, and coupled to the pad to become the collector of the BJT;
a P-type base region, formed on the buried layer to become the base of the BJT; and
an N-type emitter, formed in the base region and coupled to the power line to become the emitter of the BJT, the emitter being a strip with at least one winding.

11. The ESD protection circuit in claim 1, wherein an emitter contact region is formed in the base region as the electric contact of the base region.

12. The ESD protection circuit in claim 10, wherein the emitter has a serpentine pattern.

13. The ESD protection circuit in claim 10, wherein the emitter has a finger-type pattern.
